(19) United States
(12) Patent Application Publication
(10) Pub. No.: US 2018/0301580 A1
(43) Pub. Date: Oct. 18, 2018

(54) COMPOUND SEMICONDUCTOR SOLAR CELL

(71) Applicant: LG ELECTRONICS INC., Seoul (KR)

(72) Inventors: Soohyun KIM, Seoul (KR); Hyun LEE, Seoul (KR); Wonseok CHOI, Seoul (KR); Younho HEO, Seoul (KR)

(73) Assignee: LG ELECTRONICS INC., Seoul (KR)

(21) Appl. No.: 15/949,628

(22) Filed: Apr. 10, 2018

(30) Foreign Application Priority Data
Apr. 13, 2017 (KR) 10-2017-0047917

(51) Int. Cl. H01L 31/0725; H01L 31/0735

(52) U.S. Cl. CPC H01L 31/0725; H01L 31/0735

(57) ABSTRACT

According to an aspect of the present invention, there is provided a compound semiconductor solar cell, comprising a first cell, the first cell including: a first base layer formed of a gallium indium phosphide (GaInP)-based compound semiconductor; a first emitter layer forming a p-n junction with the first base layer; a first window layer positioned on a front surface of the first base layer or the first emitter layer; and a first back surface field layer positioned on a back surface of the first emitter layer or the first base layer, wherein the first window layer of the first cell is formed of a four-component III-V compound semiconductor.

### CROSS-REFERENCE TO RELATED APPLICATION

This application claims priority to and the benefit of Korean Patent Application No. 10-2017-0047917 filed in the Korean Intellectual Property Office on Apr. 13, 2017, the entire contents of which are incorporated herein by reference.

### BACKGROUND OF THE INVENTION

### Field of the Invention

Embodiments of the invention relate to a compound semiconductor solar cell, and more particularly, to a compound semiconductor solar cell having a first cell serving as a top cell including a gallium indium phosphide (GaInP) based compound semiconductor layer.

### Background of the Related Art

A compound semiconductor is not made of a single element such as silicon (Si) and germanium (Ge) and is formed by a combination of two or more kinds of elements to operate as a semiconductor. Various kinds of compound semiconductors have been currently developed and used in various fields. The compound semiconductors are typically used for a light emitting element, such as a light emitting diode and a laser diode, and a solar cell using a photoelectric conversion effect, a thermoelectric conversion element using a Peltier effect, and the like.

A compound semiconductor solar cell includes a compound semiconductor layer formed of a III-V compound semiconductor such as gallium arsenide (GaAs), indium phosphide (InP), gallium indium phosphide (GaInP), aluminum indium phosphide (AlInP), aluminum gallium indium phosphide (AlGaInP), gallium aluminum arsenide (GaAlAs) and gallium indium arsenide (GaInAs), a II-VI compound semiconductor such as cadmium sulfide (CdS), cadmium tellurium (CdTe) and zinc sulfide (ZnS), a compound semiconductor such as copper indium selenium (CuInSe₂).

A compound semiconductor solar cell having the compound semiconductor layer formed of a III-V compound semiconductor has a single junction structure including one cell and a multi junction structure including at least two cells. In a compound semiconductor solar cell having a multi junction structure, a base layer of a first cell, which is located on a side where light is incident and serves as a top cell, and an emitter layer form a p-n junction with the base layer are typically formed of a GaInP-based compound semiconductor, and a base layer and an emitter layer of a second cell located on a back surface of the first cell are typically formed of a GaAs-based compound semiconductor.

In the compound semiconductor solar cell having such a constitution, the first cell further includes a first window layer and a first back surface field layer (BSF), and in order to improve the efficiency of the solar cell, the first window layer and the first back surface field layer are formed of a material having the largest band gap among III-V compound semiconductors.

Therefore, when the ELO (epitaxial lift off) process is not used in the process of manufacturing a compound semiconductor solar cell, among the III-V group compound semiconductors, AlInP, which has the largest band gap, can form the first window layer and the back surface field layer.

However, AlInP forming the first window layer and the first back surface field layer is easily dissolved in hydrofluoric acid (HF) used for removing a sacrificial layer in the ELO process.

Therefore, when the ELO process is performed using hydrofluoric acid, the hydrofluoric acid penetrates into the periphery of the particles present on a mother substrate, the layer formed of AlInP, in particular the first window layer, is selectively dissolved by hydrofluoric acid, and as a result, a defect in which the compound semiconductor layer around the particle is broken.

Due to such a problem, when the compound semiconductor solar cell is manufactured using the ELO process, the first window layer and the first back surface field layer, in particular, the first window layer cannot be formed of AlInP.

Therefore, it is required to develop a compound semiconductor solar cell capable of suppressing the occurrence of defects due to hydrofluoric acid used in the ELO process while using the ELO process.

### SUMMARY OF THE INVENTION

It is an object of the present invention to provide a compound semiconductor solar cell capable of suppressing the occurrence of defects due to hydrofluoric acid used in an ELO process while using an ELO process.

According to an aspect of the present invention, there is provided a compound semiconductor solar cell, comprising a first cell, the first cell including: a first base layer formed of a GaInP-based compound semiconductor; a first emitter layer forming a p-n junction with the first base layer; a first window layer positioned on a front surface of the first base layer or the first emitter layer; and a first back surface field layer positioned on a back surface of the first emitter layer or the first base layer, wherein the first window layer of the first cell is formed of a four-component III-V compound semiconductor.

In an embodiment of the present invention, the first window layer may be formed of AlGaInP having a band gap characteristic similar to AlInP and having little or no dissolution due to hydrofluoric acid used in the ELO process. The band gap characteristics of AlGaInP can be controlled by appropriately adjusting the content of aluminum (Al).

In this case, the first window layer is formed of AlGaInP having an aluminum content of 45 to 70 when the sum of the contents of aluminum and gallium is 100.

That is, the first window layer may be formed of AlₓGa₁₋ₓInP having X of 0.45 to 0.7.

The first window layer may be formed to a thickness of 20 to 35 nm.

The first back surface field layer may be formed of the same material as the first window layer, and may be thicker than the first window layer.

For example, the first back surface field layer may be formed to a thickness of 50 to 100 nm.

The first emitter layer may form a homojunction or a heterojunction with the first base layer.

The first base layer and the first window layer may be doped with at least one n-type impurity selected from silicon (Si), selenium (Se) and tellurium (Te), respectively, and the first emitter layer and the first back surface field layer may be doped with p-type impurity, respectively.

The compound semiconductor solar cell according to another aspect of the present invention may further include a second cell positioned on a back surface of the first cell.

The second cell may include a second base layer formed of a GaAs-based compound semiconductor, a second emitter layer forming a p-n junction with the second base layer, a second window layer, and a second back surface field layer. The second window layer and the second back surface field layer are formed of GaInP, respectively.

The second base layer and the second window layer may be doped with at least one n-type impurity selected from silicon (Si), selenium (Se) and tellurium (Te), respectively, and the first emitter layer and the first back surface field layer may be doped with p-type impurity, respectively.

A first tunnel layer may be disposed between the first cell and the second cell, and the first tunnel layer may include a first layer in contact with the first back surface field layer and a second layer in contact with the second window layer. The first layer may be made of AlGaAs doped with p-type impurity at a higher concentration than the first back surface field layer, and the second layer may be made of GaInP doped with n-type impurity at a higher concentration than the second window layer.

The compound semiconductor solar cell according to another aspect of the present invention may further include a third cell positioned on a back surface of the second cell.

The third cell may include a third base layer formed of a GaAs-based compound semiconductor, a third emitter layer forming a p-n junction with the third base layer, a third window layer, and a third back surface field layer.

The third window layer and the third back surface field layer may be formed of aluminum indium gallium arsenide (AlInGaAs), respectively.

The third base layer and the third window layer may be doped with at least one n-type impurity selected from silicon (Si), selenium (Se) and tellurium (Te), respectively, and the first emitter layer and the first back surface field layer may be doped with p-type impurity, respectively.

A second tunnel layer may be disposed between the second cell and the third cell, and the second tunnel layer may include a third layer in contact with the second back surface field layer and a fourth layer in contact with the third window layer. The third layer may be made of GaAs doped with p-type impurity at a higher concentration than the second back surface field layer, and the fourth layer may be made of GaAs doped with n-type impurity at a higher concentration than the third window layer.

A metamorphic layer may be disposed between the second tunnel layer and the third cell.

The compound semiconductor solar cell according to the present invention forms the first window layer of the first cell with AlGaInP having a large band gap without being dissolved by hydrofluoric acid used in the ELO process. Accordingly, defects caused by the penetration of hydrofluoric acid into the periphery of the particles in the ELO process are suppressed, and thus a highly efficient compound semiconductor solar cell can be obtained.

### BRIEF DESCRIPTION OF THE DRAWINGS

FIG. 1 is a cross-sectional view of a compound semiconductor solar cell according to a first embodiment of the present invention.

FIG. 2 is a band gap diagram showing the band gap of AlGaInP according to the composition ratio of aluminum (Al) and gallium (Ga).

FIG. 3 is an image showing defects formed by hydrofluoric acid penetration in a conventional solar cell in which the first window layer and the first back surface field layer of the first cell are formed of AlInP.

FIG. 4 is an image showing defects formed due to hydrofluoric acid penetration in the solar cell of FIG. 1 in which the first window layer and the first back surface field layer of the first cell are formed of AlGaInP.

FIG. 5 is a cross-sectional view of a compound semiconductor solar cell according to a second embodiment of the present invention.

FIG. 6 is a cross-sectional view of a compound semiconductor solar cell according to a third embodiment of the present invention.

### DETAILED DESCRIPTION OF THE EMBODIMENTS

Reference will now be made in detail to embodiments of the invention examples of which are illustrated in the accompanying drawings. Since the invention may be modified in various ways and may have various forms, specific embodiments are illustrated in the drawings and are described in detail in the specification. However, it should be understood that the invention are not limited to specific disclosed embodiments, but include all modifications, equivalents and substitutes included within the spirit and technical scope of the invention.

The terms ‘first’, ‘second’, etc., may be used to describe various components, but the components are not limited by such terms. The terms are used only for the purpose of distinguishing one component from other components.

For example, a first component may be designated as a second component without departing from the scope of the embodiments of the invention. In the same manner, the second component may be designated as the first component.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hand, when an arbitrary component is described as “being directly connected to” or “being directly linked to” another component, this should be understood to mean that no other component exists between them.

The terms used in this application are used to describe only specific embodiments or examples, and are not intended to limit the invention. A singular expression can include a plural expression as long as it does not have an apparently different meaning in context.

In this application, the terms “include” and “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the invention pertains.

The terms defined in a generally used dictionary must be understood to have meanings identical to those used in the context of a related art, and are not to be construed to have ideal or excessively formal meanings unless they are obviously specified in this application.

The following example embodiments of the invention are provided to those skilled in the art in order to describe the invention more completely. Accordingly, shapes and sizes of elements shown in the drawings may be exaggerated for clarity.

Hereinafter, a compound semiconductor solar cell according to the present invention will be described with reference to the accompanying drawings.

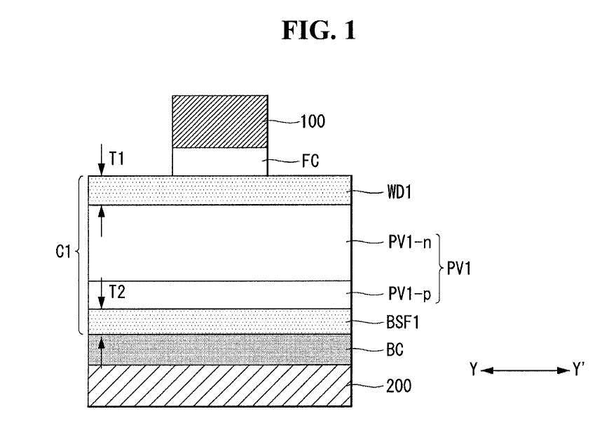

FIG. 1 is a cross-sectional view of a compound semiconductor solar cell according to a first embodiment of the present invention.

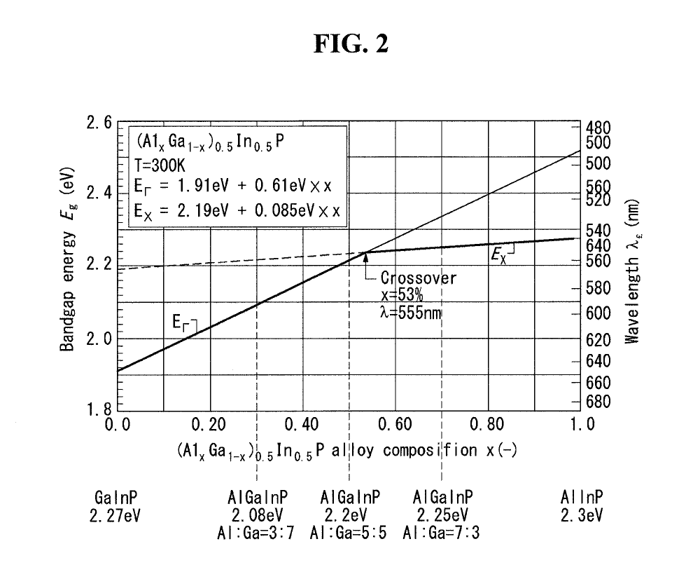

FIG. 2 is a band gap diagram showing the band gap of AlGaInP according to the composition ratio of aluminum (Al) and gallium (Ga).

FIG. 3 is an image showing defects formed by hydrofluoric acid penetration in a conventional solar cell in which the first window layer and the first back surface field layer of the first cell are formed of AlInP.

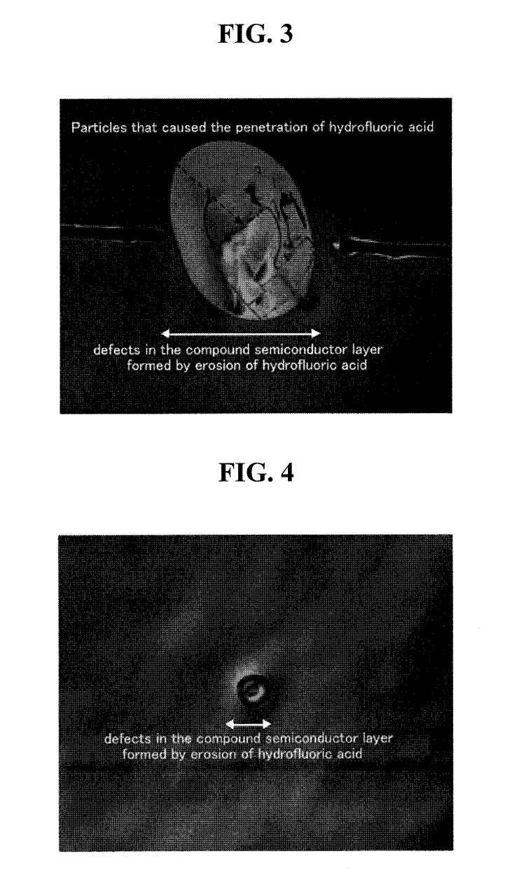

FIG. 4 is an image showing defects formed due to hydrofluoric acid penetration in the solar cell of FIG. 1 in which the first window layer and the first back surface field layer of the first cell are formed of AlGaInP.

The compound semiconductor solar cell according to the first embodiment of the present invention will be described with reference to FIGS. 1 to 4. The compound semiconductor solar cell of the first embodiment is a single junction solar cell including only one cell, that is, the first cell C1. The first cell C1 includes a first light absorbing layer PV1, a first window layer WD1 positioned on a front surface of the first light absorbing layer PV1, a first back surface field layer BSF1 positioned on a back surface of the first light absorbing layer PV1, a front contact layer FC positioned on a front surfaces of the first window layer WD1, and a back contact layer BC positioned on a back surface of the first back surface field layer BSF1.

The compound semiconductor solar cell of the first embodiment may further includes a grid-shaped front electrode 100 positioned on a front contact layer FC and a sheet-shaped back electrode 200 positioned on a back surface of the back contact layer BC.

The first light absorbing layer PV1 includes a first base layer PV1-n including an n-type impurity and in contact with the first window layer WD1, and a first emitter layer PV1-p which forms a p-n junction with the first base layer PV1-n and is positioned on the back surface of the first base layer PV1-n. The first base layer PV1-n and the first emitter layer PV-p are formed of a GaInP-based compound semiconductor, respectively.

For example, the first base layer PV1-n is formed of n-type GaInP, and the first emitter layer PV1-p is formed of p-type GaInP.

The p-type impurity doped in the first emitter layer PV1-p may be selected from carbon (C), magnesium (Mg), zinc (Zn), or a combination thereof, and the n-type impurity doped in the first base layer PV1-n may be selected from silicon (Si), selenium (Se), tellurium (Te), or a combination thereof.

The first base layer PV1-n may be positioned in a region adjacent to the front electrode 100. The first emitter layer PV1-p may be positioned in a region directly under the first base layer PV1-n and may be positioned in a region adjacent to the back electrode 200.

That is, the interval between the first base layer PV1-n and the front electrode 100 is smaller than the interval between the first emitter layer PV1-p and the front electrode 100, and the interval between the first base layer PV1-n and the back electrode 200 is larger than the interval between the first emitter layer PV1-p and the back electrode 200.

As a result, a p-n junction in which the first emitter layer PV1-p and the first base layer PV1-n are joined is formed in the first light absorbing layer PV1. The electron-hole pairs generated by the light are separated into electrons and holes by the internal potential difference formed by the p-n junction of the first light absorbing layer PV1 so that electrons move toward the n-type semiconductor layer PV1-n and holes move toward the p-type semiconductor layer PV1-p.

Therefore, the holes generated in the first light absorbing layer PV1 move to the second electrode 200 through the back contact layer BC and the electrons generated in the first light absorbing layer PV1 moves to the front electrode 100 through the first window layer WD1 and the front contact layer FC.

Alternatively, the first emitter layer PV1-p may be positioned in a region adjacent to the front electrode 100 and the first base layer PV1-n may be positioned in a region directly under the first emitter layer PV1-p and may be positioned in a region adjacent to the back electrode 200. In this instance, the holes generated in the first light absorbing layer PV1 move to the front electrode 100 through the front contact layer FC and the electrons generated in the first light absorbing layer PV1 move to the back electrode 200 through the back contact layer BC.

In the case where the first light absorbing layer PV1 further includes the back surface field layer BSF1, the back surface field layer BSF1 may have the same conductivity as the upper layer, that is, the first emitter layer PV1-p and may be formed of the same material as the first window layer WD1.

In order to effectively block the movement of the charge (holes or electrons) to be moved toward the front electrode 100 toward the back electrode 200, the first back surface field layer BSF1 is formed entirely on the back surface of the upper layer directly contacting with the first back surface field layer BSF1, that is, the first emitter layer PV1-p.

That is, in the solar cell shown in FIG. 1, in the case where the first back surface field layer BSF1 is formed on the back surface of the first emitter layer PV1-p, the first back surface field layer BSF1 functions to block the movement of electrons toward the second electrode 200. In order to effectively block the movement of electrons toward the second electrode 200, the first back surface field layer BSF1 is positioned on the entire back surface of the first emitter layer PV1-p.

In the case of homogeneous junction, the first emitter layer PV1-p and the first base layer PV1-n may be made of the same material having the same band gap. Alternatively, in the case of heterojunction, the first emitter layer PV1-p and the first base layer PV1-n may be made of different materials having different band gaps.

In the case of the homogeneous junction, the first base layer PV1-n may be formed of n-type GaInP, and the first emitter layer PV1-p may be formed of p-type GaInP.

The first window layer WD1 may be formed between the first light absorbing layer PV1 and the front electrode 100 and may be formed by doping an n-type impurity into a four component III-VI group semiconductor compound.

However, when the first emitter layer PV1-p is positioned on the first base layer PV1-n and the first window layer WD1 is positioned on the first emitter layer PV1-p, the first window layer WD1 may include a first conductivity type (i.e., a p-type) impurity.

The first window layer WD1 serves to passivate the front surface of the first light absorbing layer PV1. Therefore, when the carrier (electrons or holes) moves to the surface of the first light absorbing layer PV1, the first window layer WD1 can prevent the carriers from recombining on the surface of the first light absorbing layer PV1.

Since the first window layer WD1 is disposed on the front surface (i.e., light incident surface) of the first light absorbing layer PV1, in order to prevent light incident on the first light absorbing layer PV1 from being absorbed, the first window layer WD1 may have an energy band gap higher than the energy band gap of the first light absorbing layer PV1.

In addition, it is necessary to form the first window layer WD1 with a substance which is difficult to dissolve in the ELO process using hydrofluoric acid.

Therefore, in the present invention, the first window layer WD1 is formed of AlGaInP instead of AlInP.

AlGaInP can exhibit band gap characteristics similar to AlInP by appropriately adjusting the content of aluminum (Al), and can inhibit the dissolution phenomenon by hydrofluoric acid used in the ELO process, unlike AlInP.

Referring to FIG. 2, the band gap of AlGaInP is directly or indirectly transitioned when the content of aluminum is 53%. In the section where the content of aluminum is 53% or less, the band gap decreases sharply as the aluminum content decreases. In the section where the content of aluminum is 53% or more, the band gap is almost similar to that of AlInP.

For example, when the content of aluminum is 50%, that is, when the content of aluminum and gallium is 1:1, AlGaInP has a band gap of 2.22 Ev similar to 2.3 eV, which is the band gap of AlInP.

As a result of testing the dissolution tendency of AlGaInP according to the content of aluminum, it was found that when the content of aluminum exceeds 70%, defects having a size of 100 μm or more are generated after the ELO process.

Therefore, it is desirable to control the aluminum content within a range capable of suppressing the occurrence of defects due to hydrofluoric acid, having a band gap similar to AlInP, for example, a band gap of 2.2 eV or more. The content of aluminum satisfying the above-mentioned conditions is in the range of 45 to 70% when the content of aluminum and gallium is 100.

Here, the reason why the minimum content of aluminum is limited to 45% is that the band gap of AlGaInP is set to 2.2 eV or more, and the reason why the maximum content of aluminum is limited to 70% is to suppress the dissolution by hydrofluoric acid.

Therefore, it is preferable that the first window layer WD1 is formed of n-type AlₓGa₁₋ₓInP having X of 0.45 to 0.7.

Referring to FIG. 3, in the case where the first window layer WD1 is formed of AlInP, after the ELO process is performed for 8 hours, the compound semiconductor layer at the periphery of the particle having a size of about 10 μm or less is eroded by hydrofluoric acid, abd defects having a size of about 800 μm were generated.

However, in the case where the first window layer WD1 is formed of n-type AlxGa1-xInP with X of 0.45 to 0.7, after the ELO process is performed for 8 hours, although the compound semiconductor layer at the periphery of the particles having a size of about 10 μm or less is eroded by hydrofluoric acid, the amount of erosion of the compound semiconductor layer is very small. Thus, defects having a size of about 80 μm are generated.

Thus, when the first window layer WD1 is formed of n-type AlxGa1-xInP having X of 0.45 to 0.7, generation of defects due to hydrofluoric acid can be suppressed while realizing a band gap similar to that of AlInP.

The first window layer WD1 formed of AlGaInP may be formed to have a thickness T1 of 20 to 35 nm and the first back surface field layer BSF1 may be formed of the same material as the first window layer WD1.

The first back surface field layer BSF1 may be thicker than the thickness T1 of the first window layer WD1. As an example, the first back surface field layer BSF1 may be formed with a thickness T2 of 50 to 100 nm.

The antireflection film may be disposed in a region other than the region where the front electrode 100 and/or the front contact layer FC are located in the front surface of the first window layer WD1.

Alternatively, the antireflection film may be disposed on the front contact layer FC and the front electrode 100 as well as the exposed first window layer WD1.

The compound semiconductor solar cell may further include a bus bar electrode physically connecting the plurality of front electrodes 100, and the bus bar electrode may be exposed to the outside without being covered by the antireflection film.

The antireflection film having such a structure may include magnesium fluoride, zinc sulfide, titanium oxide, silicon oxide, a derivative thereof, or a combination thereof.

The front electrode 100 may extend in the first direction and may be spaced apart from each other by a predetermined distance along a second direction Y-Y ‘orthogonal to the first direction.

The front electrode 100 having such a structure may be formed to include an electrically conductive material. For example, the front electrode 100 may include at least one of gold (Au), germanium (Ge), and nickel.

The front contact layer FC positioned between the first window layer WD1 and the front electrode 100 is formed by doping the second impurity with a dopant concentration higher than the impurity doping concentration of the first base layer PV1-n into the III-V compound semiconductor. For example, the front contact layer may be formed of n+-type GaAs.

The front contact layer FC forms an ohmic contact between the first window layer WD1 and the front electrode 100. That is, when the front electrode 100 directly contacts the first window layer WD1, the ohmic contact between the front electrode 100 and the light absorbing layer PV1 is not well formed because the impurity doping concentration of the first window layer WD1 is low. Therefore, the carrier moved to the first window layer WD1 cannot move to the front electrode 100 and can be destroyed.

However, when the front contact layer FC is formed between the front electrode 100 and the first window layer WD1, since the front contact layer FC forms an ohmic contact with the front electrode 100, the carrier is smoothly moved and the short circuit current density Jsc of the compound semiconductor solar cell increases. Thus, the efficiency of the solar cell can be further improved.

The front contact layer FC may be formed in the same shape as the front electrode 100.

A back contact layer BC disposed on the back surface of the first back surface field layer BSF1 is entirely formed on the back surface of the first back surface field layer BSF1. The back contact layer BC may be formed by doping the first conductive type impurity into the III-VI group semiconductor compound. For example, the back contact layer BC may be formed of p-type GaAs.

The back contact layer BC forms an ohmic contact with the back electrode 200, so that the short circuit current density Jsc of the compound semiconductor solar cell can be further improved. Thus, the efficiency of the solar cell can be further improved.

The thickness T1 of the front contact layer FC and the thickness T2 of the back contact layer BC may each be 100 to 300 nm. For example, the front contact layer FC may be formed with a thickness T1 of 100 nm and the back contact layer BC may be formed with a thickness T2 of 300 nm.

The back electrode 200 positioned on the back surface of the back contact layer BC may be a sheet-like conductive layer positioned entirely on the back surface of the back contact layer BC, different from the front electrode 100. That is, the back electrode 200 may be referred to as a sheet electrode located on the entire back surface of the back contact layer BC.

At this time, the back electrode 200 may be formed in the same plane as the first light absorbing layer PV1 and may be formed of at least one material selected from the group consisting of gold (Au), platinum (Pt), titanium (Ti), tungsten (W), silicon (Si), nickel (Ni), magnesium (Mg), palladium (Pd), copper (Cu), and germanium (Ge). The material forming the back electrode 200 may be suitably selected according to the conductivity type of the back contact layer BC.

For example, when the back contact layer BC contains a p-type impurity, the back electrode 200 may be formed any one of gold (Au), platinum/titanium (Pt/Ti), tungsten-silicon alloy (WSi), and silicon/nickel/magnesium/nickel (Si/Ni/Mg/Ni). Preferably, the back electrode 200 may be formed of gold (Au) having a low contact resistance with the p-type back contact layer BC.

If the back contact layer BC contains n-type impurities, the back electrode 200 may be formed any one of palladium/gold (Pd/Au), copper/germanium (Cu/Ge), nickel/germanium-gold alloy/nickel (Ni/GeAu/Ni), gold/titanium (Au/Ti). Preferably, the back electrode 200 may be formed of palladium/gold (Pd/Au) having a low contact resistance with the p-type back contact layer BC.

However, the material forming the back electrode 200 can be appropriately selected among the materials, and in particular, can be appropriately selected from materials having low contact resistance with the back contact layer BC.

A compound semiconductor solar cell having such a configuration can be formed by an ELO method.

The method for manufacturing the compound semiconductor solar cell comprises epitaxially growing a sacrificial layer on a mother substrate, epitaxially growing a compound semiconductor layer on the sacrificial layer, forming the back electrode on the back surface of the compound semiconductor layer, separating the compound semiconductor layer and the back electrode from the mother substrate by removing the sacrificial layer by an epitaxial lift-off process, and forming the first electrode on the front surface of the compound semiconductor layer.

More detail, a sacrificial layer is formed on one side of the mother substrate serving as a base layer for providing a suitable lattice structure in which the compound semiconductor layer is formed, and the compound semiconductor layer is formed on the sacrificial layer.

Here, the compound semiconductor layer may be manufactured by sequentially stacking the front contact layer FC formed of n+-type GaAs, the first window layer WD1 formed of n-type AlₓGa₁₋ₓInP having X of 0.45 to 0.7, the first base layer PV1-n formed of n-type GaInP, the first emitter layer PV1-p formed of p-type GaInP, the first back surface field layer BSF1 formed of p-type AlₓGa₁₋ₓInP having X of 0.45 to 0.7, and the back contact layer BC formed of p-type GaAs.

When the first window layer WD1 and the first back surface field layer BSF1 are formed of AlₓGa₁₋ₓInP having X of 0.45 to 0.7, the ELO process is performed to remove the sacrificial layer, it is possible to suppress the occurrence of defects due to the erosion of the compound semiconductor layer around the particle.

After the ELO process using hydrofluoric acid is performed to separate the compound semiconductor layer and the back electrode from the mother substrate, the front electrode 100 is formed on the front surface of the compound semiconductor layer, in particular, on the front contact layer. Patterning the front contact layer not covered by the front electrode 100 by using the front electrode 100 as a mask. The compound semiconductor solar cell shown in FIG. 1 is manufactured.

Although the compound semiconductor solar cell has a single junction structure including only the first cell C1, the compound semiconductor solar cell of the present invention has a multi junction structure having a plurality of cells.

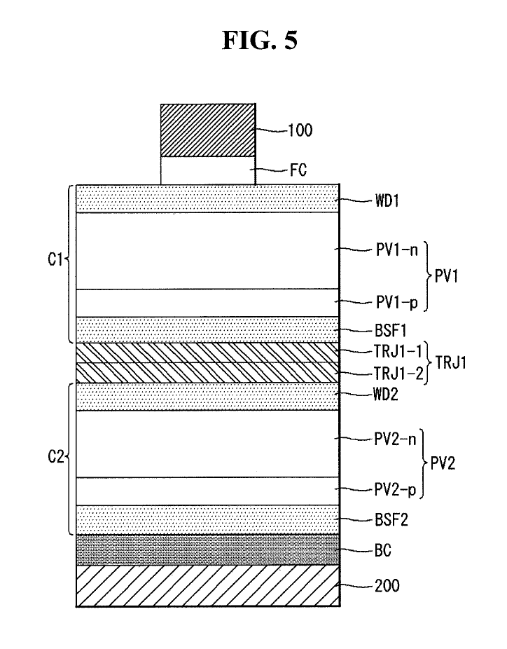

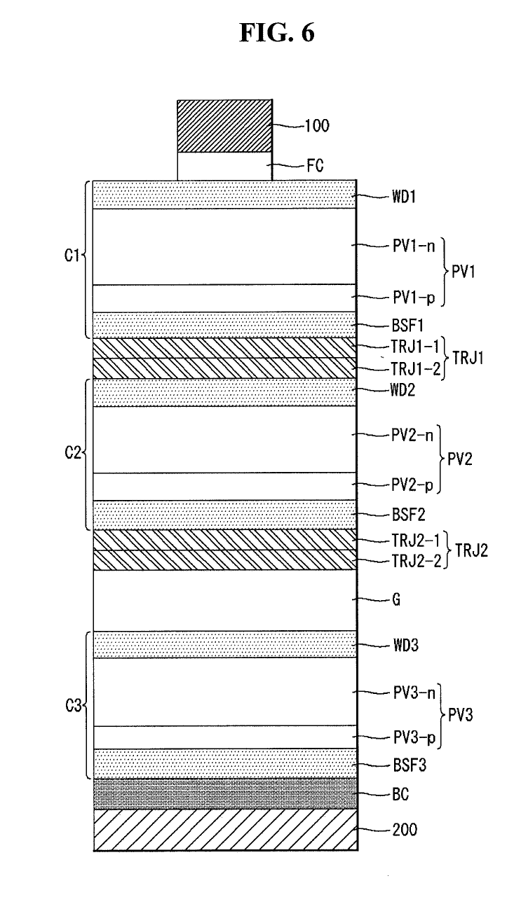

As shown in FIG. 5, the compound semiconductor solar cell includes the first cell C1 of FIG. 1, the second cell C2 positioned on the back surface of the first cell C1, and a first tunnel layer TRJ1 positioned between the first cell C1 and the second cell C2.

The second cell C2 may comprise a second base layer PV2-n formed of GaAs-based compound semiconductor, for example, n-type GaAs, a second emitter layer PV2-p formed of p-type GaAs and forms a p-n junction with the second base layer PV2-n, a second window layer WD2 positioned between the first tunnel layer TRJ1 and the second base layer PV2-n and formed of n-type GaInP, and a second back surface field layer BSF2 positioned on the back surface of the second emitter layer PV2-p and formed of p-type GaAs.

Here, the second base layer PV2-n and the second emitter layer PV2-p constitute the second light absorbing layer PV2.

The second cell C2 is positioned on the back surface of the first cell C1 in order to absorb light of a long wavelength transmitted through the first cell C1 without being absorbed by the first cell C1.

Thus, the second base layer PV2-n and the second emitter layer PV2-p are formed of a material having a band gap lower than the band gap of GaInP (approximately 1.9 eV) forming the first base layer PV1-n and the first emitter layer PV1-p. For example, the second base layer PV2-n and the second emitter layer PV2-p are formed of GaAs having a band gap of approximately 1.42 eV.

The second window layer WD2 and the second back surface field layer BSF2 of the second cell C2 may be formed of a material having a band gap higher than that of the second base layer PV2-n and the second emitter layer PV2-p. For example, the second window layer WD2 and the second back surface field layer BSF2 of the second cell C2 may be formed of GaInP.

Unlike the first window layer WD1 and the first back surface field layer BSF1, the second window layer WD2 and the second back surface field layer BSF2 of the second cell C2 may not contain aluminum. This is because the band gap of the second base layer PV2-n and the second emitter layer PV2-p of the second cell C2 is lower than the band gap of the first base layer PV1-n and the first emitter layer PV1-p of the first cell C1, and erosion of the compound semiconductor layer around the particle is suppressed by the first window layer WD1.

The first tunnel layer TRJ1 includes a first layer TRJ1 formed of p+-type AlGaAs doped with a higher concentration of p-type impurity than the first back surface field layer BSF1 and in contact with the first back surface field layer BSF1, and a second layer TRJ1-2 formed of n+-type GaInP doped with an n-type impurity at a higher concentration than the second window layer WD2 and in contact with the second window layer WD2.

Since the back contact layer BC is formed for the ohmic contact of the back electrode 200, in the compound semiconductor solar cell having the double junction structure, the back contact layer BC is positioned between the second back surface field layer BSF2 and the back electrodes 200.

Alternatively, the compound semiconductor solar cell has a triple junction structure including the first cell C1 and the second cell C2 shown in FIG. 5, a third cell C3 positioned on the back surface of the second cell C2, a second tunnel layer TRJ2 positioned between the second cell C2 and the third cell C3, and a metamorphic layer G positioned between the second tunnel layer TRJ2 and the third cell C3.

The third cell C3 may comprise a third base layer PV3-n formed of a GaAs-based compound semiconductor, for example, n-type InGaAs, a third emitter layer PV3-p forms a p-n junction with the third base layer PV3-n and formed of p-type InGaAs, a third window layer WD3 positioned between the metamorphic layer G and the third base layer PV3-n and formed of n-type AlInGaAs, and a third back surface field layer BSF3 positioned on the back surface of the third emitter layer PV3-p and formed of p-type AlInGaAs.

Here, the third base layer PV3-n and the third emitter layer PV3-p constitute the third light absorbing layer PV3.

The third cell C3 is positioned on the back surface of the second cell C2 in order to absorb light of a long wavelength transmitted through the second cell C2 without being absorbed by the second cell C2.

Thus, the third base layer PV3-n and the third emitter layer PV3-p of the third cell C3 may be formed of a material having a band gap lower than that of the second base layer PV2-n and the second emitter layer PV2-p of the second cell C2. For example, the third base layer PV3-n and the third emitter layer PV3-p of the third cell C3 may be formed of InGaAs.

The third window layer WD3 and the third back surface field layer BSF3 may be formed of a material having a band gap higher than that of the third base layer PV3-n and the third emitter layer PV3-p. For example, the third window layer WD3 and the third back surface field layer BSF3 may be formed of AlInGaAs.

The second tunnel layer TRJ2 includes a third layer TRJ2 formed of p+-type GaAs doped with a higher concentration of p-type impurity than the second back surface field layer BSF2 and in contact with the second back surface field layer BSF2, and a fourth layer TRJ2-2 formed of n-type GaAs doped with a higher concentration of n-type impurity than the third window layer WD3 and positioned on the back surface of the third layer TRJ2-1.

Since the back contact layer BC is formed for the ohmic contact of the back electrode 200, in the compound semiconductor solar cell of the triple junction structure, the back contact layer BC is positioned between the back electrodes 200 and the third back surface field layer BSF3.

Although the multi junction structure is described as a double junction or a triple junction structure in the above description, a compound semiconductor solar cell having a multi junction structure of a quadruple junction structure or more is also included in the scope of the present invention.

What is claimed is:

1. A compound semiconductor solar cell, comprising a first cell, the first cell including:
a first base layer formed of a gallium indium phosphide (GaInP)-based compound semiconductor;
a first emitter layer forming a p-n junction with the first base layer;
a first window layer positioned on a front surface of the first base layer or the first emitter layer; and
a first back surface field layer positioned on a back surface of the first emitter layer or the first base layer,
wherein the first window layer of the first cell is formed of a four-component III-V compound semiconductor.

2. The compound semiconductor solar cell of claim 1, wherein the first window layer is formed of AlₓGa₁₋ₓInP.

3. The compound semiconductor solar cell of claim 2, wherein X is 0.45 to 0.7.

4. The compound semiconductor solar cell of claim 3, wherein the first window layer is formed to a thickness of 20 to 35 nm.

5. The compound semiconductor solar cell of claim 3, wherein the first back surface field layer is formed of the same material as the first window layer.

6. The compound semiconductor solar cell of claim 5, wherein the first back surface field layer is formed thicker than the first window layer.

7. The compound semiconductor solar cell of claim 1, wherein the first emitter layer forms a homojunction or a heterojunction with the first base layer.

8. The compound semiconductor solar cell of claim 7, wherein the first base layer and the first window layer are doped with at least one n-type impurity selected from silicon (Si), selenium (Se) and tellurium (Te), respectively, and the first emitter layer and the first back surface field layer are doped with p-type impurity, respectively.

9. The compound semiconductor solar cell of claim 7, further comprising a second cell positioned on a back surface of the first cell, the second cell including,
a second base layer formed of a gallium arsenide (GaAs)-based compound semiconductor, a second emitter layer forming a p-n junction with the second base layer, a second window layer, and a second back surface field layer.

10. The compound semiconductor solar cell of claim 9, wherein the second window layer and the second back surface field layer are formed of GaInP, respectively.

11. The compound semiconductor solar cell of claim 10, wherein a first tunnel layer is positioned between the first cell and the second cell.

12. The compound semiconductor solar cell of claim 11, wherein the first tunnel layer comprises a first layer in contact with the first back surface field layer and a second layer in contact with the second window layer, and
wherein the first layer is made of aluminum gallium arsenide (AlGaAs) doped with p-type impurity at a higher concentration than the first back surface field layer, and the second layer is made of GaInP doped with n-type impurity at a higher concentration than the second window layer.
